(19) United States
(12) Patent Application Publication
(10) Pub. No.: US 2004/0125840 A1
(43) Pub. Date: Jul. 1, 2004

(54) Oxide-confined VCSEL device and the method for making the same

(76) Inventors: Wen-Jang Jiang, Taipei (TW); Chia-Pin Sung, Hsinchu (TW); Hung-Pin Yang, Hsinchu (TW); Hsin-Chieh Yu, Kaohsiung (TW)

Correspondence Address: BIRCH STEWART KOLASCH & BIRCH, PO BOX 747, FALLS CHURCH, VA, 22040-0747, US

(21) Appl. No.: 10/402,992

(22) Filed: Apr. 1, 2003

(30) Foreign Application Priority Data
Dec. 27, 2002 (TW) 091137787

(51) Int. Cl. H01S 5/00; H01S 3/08

(52) U.S. Cl. 372/46; 372/96

(57) ABSTRACT

An oxide-confined vertical cavity surface emitting laser (VCSEL) device and the method for manufacturing the same are disclosed. After completing the oxidation procedure for the oxide-confined VCSEL, a filling material is deposited on the etched groove. This procedure can planarize the etched device surface for subsequent fabrication of a metal electrode. The invention can improve the device yield and the properties at the same time.

### BACKGROUND OF THE INVENTION

1. Field of Invention

The invention relates to an oxide confined device and the manufacturing method of it. In particular, the invention relates to an oxide-confined VCSEL and the method for making the same.

2. Related Art

A rising trend in the high-speed broadband network is to utilize optical communications, which make use of many optic fiber products. The high-speed transmission system using the optic fibers as the media requires the support of a high-quality optical transceiver module. The optical transceiver module mainly includes a light-emitting device, a photo sensor, a convergent lens, a control circuit substrate, and an optic fiber connector.

The current technology light-emitting devices favors using surface-emitting and surface-detecting devices. An example is the vertical-cavity surface emitting laser (VCSEL), which emits a laser beam perpendicular to its surface. It is characterized in that an upper and a lower distributed Bragg reflectors (DBR) are utilized in forming a laser cavity. The difference of the VCSEL from the conventional edge-emitting lasers is that one does not need to employ a cutting or dry etching process to make a laser mirror as for the edge-emitting lasers. Moreover, the VCSEL has the following advantages:

(1) It emits a lowly dispersive circular laser beam, which can be easily coupled with an optic fiber.

(2) It can be rapidly modulated for uses in high-speed optic fiber network transmissions.

(3) The manufacturing technique is similar to that of silicon semiconductors and therefore is suitable for mass production of crystals.

(4) Before the device is cut and packaged, the chip can be tested at the wafer level, greatly reducing the production cost.

(5) The device can be made into a one-dimensional or two-dimensional laser array used for serial or parallel optic fiber transmissions.

According to the structure, the VCSEL can be categorized into four types: the etched air-post ones, the ion-implanted ones, the regrowth buried heterostructure ones, and the oxide confined ones. Most of the commercial products on the market are of the ion-implanted type, which only requires a simple manufacturing process and is easy for mass production. However, the implantation region cannot be too close to the active layer of the surface-emitting laser; otherwise, the high-energy particles may damage the active layer material, resulting in deterioration. Therefore, the ion-implanted VCSEL is not ideal for high-frequency operations. Nowadays, people start to consider the oxide-confined VCSEL. Its device properties are better than the ion-implanted ones. Since its light-emitting region is narrower (aperture ˜1 μm), a lower threshold current (<1 mA), a higher quantum efficiency and a lower threshold voltage (1.33V) can be obtained. The oxide confinement technology is to introduce an AlGaAs layer with high aluminum concentration near the active layer. After selective etching, the device is exposed to high-temperature water vapor. The AlGaAs layer thus reacts and gets converted into an insulating aluminum oxide dielectric layer. This achieves the effect of confining both the electrical current and photons. However, the drawbacks are that it involves complicated and difficult techniques and that the device after etching has an uneven surface. For subsequent metal electrode manufacturing processes that have to cross the uneven surface, breaking may happen and thus result in a lower yield.

### SUMMARY OF THE INVENTION

To improve from the prior art, one has to solve the nonplanar surface problem caused by the selective etching process. According to the invention, a metal is deposited in the etched groove formed by the selective etching after the oxidation process. Therefore, the etched surface is planarized for subsequent electrode formation.

To achieve the above-mentioned objective, the invention fills in the etched groove on the cavity device with a filling material. The oxide-confined VCSEL includes the etched groove surrounding the device. The etched groove is formed by etching the device surface until the selective oxide current confinement region, so that the AlGaAs layer in the selective oxide current confinement region is turned into an insulating aluminum oxide dielectric layer. A filling material is inserted into the etched groove to form a filling wall, planarizing the device surface. The above process can facilitate the formation of a metal electrode on the device surface. If the filling material is conductive, then an insulating material is further used to cover the filling wall before the metal electrode formation.

In addition, the invention also discloses the manufacturing method of the oxide-confined VCSEL. First, a cavity device is provided, in the multi-layered epitaxy structure of which contains a selective oxide current confinement region. An etched groove is formed on the surface surrounding the device. The depth of the etched groove has to be enough to pass the selective oxide current confinement region. The selective oxide current confinement region is oxidized through the etched groove so that part of the AlGaAs layer is turned into an insulating aluminum oxide layer. A filling material is then inserted into the etched groove, planarizing the device surface. Finally, a metal electrode is formed on the planarized surface. The invention can be implemented with the semiconductor technology. For example, the etched groove surrounding the selective oxide current confinement region can be achieved by selective etching. One may also choose to use the lithography and the evaporation techniques to deposit the filling material.

In particular, the filling material may be a metal with an appropriate reflection rate. In addition to planarizing the etched device surface, the metal filling wall can further reflect photons output from the active layer in the horizontal direction, so that the photons can return to the active layer to keep exciting electron-hole pairs. Since metals have a better thermal conductivity, the VCSEL with the metal filling wall also has a superior high-temperature operation ability.

### BRIEF DESCRIPTION OF THE DRAWINGS

The invention will become more fully understood from the detailed description given hereinbelow illustration only, and thus are not limitative of the present invention, and wherein:

FIG. 1 shows schematically the structure of an embodiment of the invention;

FIG. 2 is a manufacturing flowchart of an embodiment of the invention;

FIG. 3 shows the relation between the optical power and the supplied electrical current for the disclosed VCSEL and a conventional VCSEL; and

FIG. 4 shows the relation between the threshold current and the temperature for an embodiment of the invention.

### DETAILED DESCRIPTION OF THE INVENTION

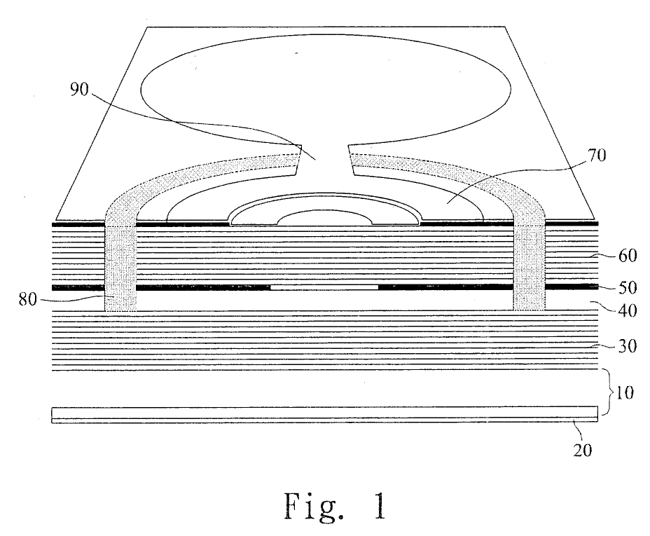

With reference to FIG. 1, the structure of an embodiment of the invention contains a substrate 10. One surface of the substrate 10 is connected with an n-type electrode 20. The other surface of the substrate 10 is stacked with, from bottom to top, an n-type Bragg reflector 30, an active layer 40, a selective oxide current confinement region 50, a p-type Bragg reflector 60, and a p-type electrode 70 to form an oxide-confined cavity device. The structure also includes an etched groove 80 surrounding the selective oxide current confinement region 50. The groove 80 is etched from the device surface down to the selective oxide current confinement region 50. Afterwards, a filling material is filled inside the etched groove 80 to form a filling wall, planarizing the etched cavity device surface. Finally, the planarized cavity device surface is formed with a metal electrode 90, which cross the filling wall and is connected to the p-type electrode 70 for electrical communications.

As shown in FIG. 1, the n-type Bragg reflector 30 works as the bottom laser mirror and the p-type Bragg reflector 60 as the top laser mirror. The n-type Bragg reflector 30 and the p-type Bragg reflector 60 are comprised of tens of pairs of materials with high and low indices of refraction. The thickness of the Bragg reflectors is λ/4, and the reflection rate has to be above 98%. The active layer 40 is made of a quantum well and a cover layer. The center is an active light-emitting region and has a thickness of λ or integer multiples of λ. The selective oxide current confinement region 50 is an AlGaAs epitaxial layer with high aluminum concentration (0.9 mole partial rate). When placing the AlGaAs in high-temperature water vapor environment, the oxidation rate rapidly goes up with the aluminum concentration. Therefore, the selective oxide current confinement region is oxidized toward the center from the area exposed via the etched groove 80, forming an oxide aperture with low index of refraction near the active layer 40. The oxidized part surrounding the selective oxide current confinement region 50 provides perfect insulation, restricting the electrical current to flow toward the active light-emitting region in the center of the active layer 40. Since it has a lower index of refraction than the adjacent semiconductor material, it can simultaneously provide photon confinement effects as a wave guide. The n-type electrode 20 may be AuGe, Ni or Au. The p-type electrode 70 may be Ti, Pt, or Au. The substrate is an n-type heavily doped GaAs or InP.

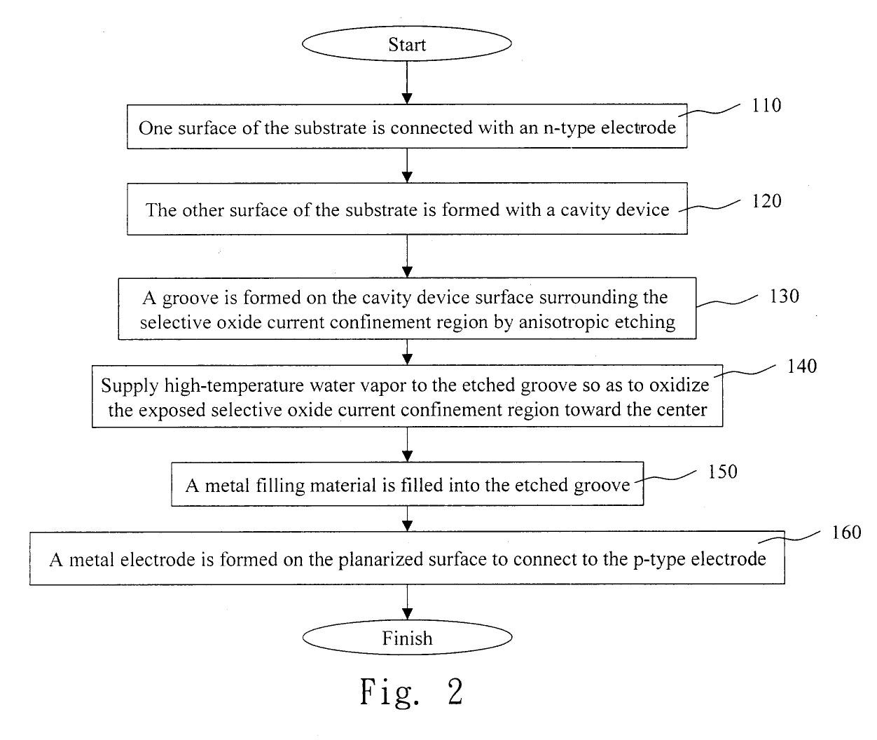

To explain the manufacturing method of the invention, please refer to FIG. 2. First, a substrate is provided. One surface of the substrate is connected with an n-type electrode (step 110). The other surface of the substrate is formed with a cavity device (step 120). The cavity device is stacked with, from bottom to top, an n-type Bragg reflector, an active layer, a selective oxide current confinement region, a p-type Bragg reflector, and a p-type electrode. A groove is formed on the cavity device surface surrounding the selective oxide current confinement region by anisotropic etching (step 130). The depth of the etched groove has to be large enough to pass the selective oxide current confinement region. Supply high-temperature water vapor to the etched groove so as to oxidize the exposed selective oxide current confinement region toward the center (step 140). In this step, the outer AlGaAs layer is turned into an insulating aluminum oxide dielectric layer, forming an oxide aperture with a low index of refraction near the active layer. A metal filling material is filled into the etched groove (step 150), planarizing the etched cavity device surface. Finally, a metal electrode is formed on the planarized surface to connect to the p-type electrode (step 150).

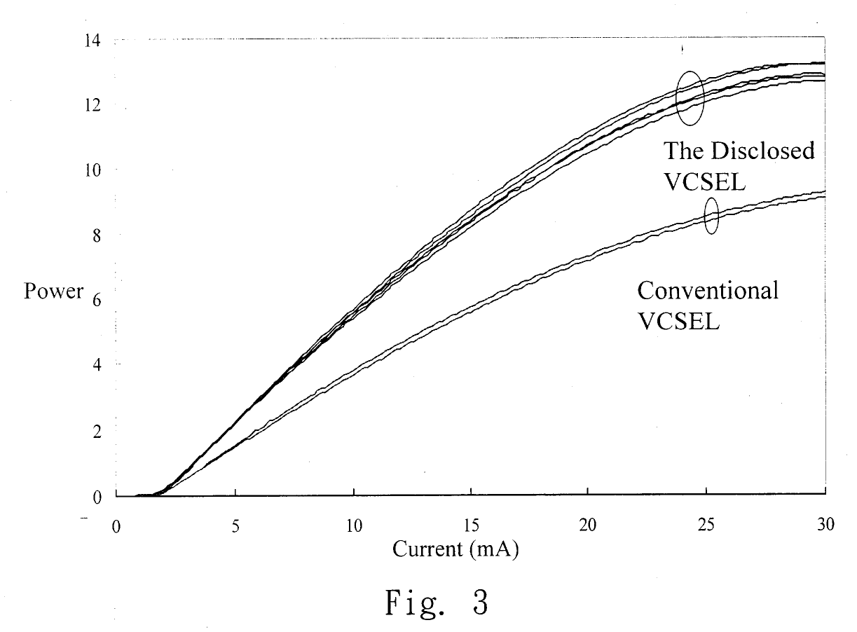

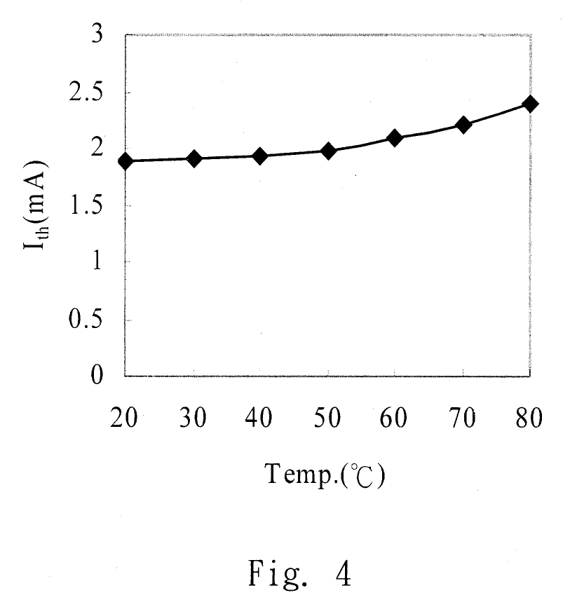

The groove can be formed using high-quality anisotropic etching according to the invention, so that the side surface of the selective oxide current confinement region with high aluminum concentration under the epitaxial structure is exposed to the environment. The groove thus formed is filled with a metal with an appropriate reflection rate and thermal conductivity. The filled metal can reflect non-resonant photons generated by the active layer in the horizontal direction back to the active layer to keep exciting electron-hole pairs. This can produce more excited photons to increase the device efficiency. The metal can be highly reflective materials such as aluminum and silver. FIG. 3 shows the relation between the optical power and the supplied electrical current for the disclosed VCSEL and a conventional VCSEL. The vertical axis is the optical power and the horizontal axis is the current. From the plot, it is clear that the invention has a higher optical power than the prior art for the same operating current. Furthermore, the superior thermal conductivity of the metal renders a better high-temperature operation ability. As shown in FIG. 4, where the vertical axis is the threshold current Iₜₕ and the horizontal axis is the temperature Temp, the threshold current only slightly goes up with the temperature for the invention.

Certain variations would be apparent to those skilled in the art, which variations are considered within the spirit and scope of the claimed invention.

What is claimed is:

1. An oxide-confined vertical cavity surface emitting laser (VCSEL) having a selective oxide current confinement region established on the surface of a substrate and an etched groove passing through the selective oxide current confinement region on the VCSEL surface to turn an exposed AlGaAs layer surrounding the selective oxide current confinement region into an insulating aluminum oxide layer, forming an oxide aperture with a low index of refraction, is characterized in that: the etched groove is filled with a filling material to form a filling wall, planarizing the surface of the VCSEL, and a metal electrode is formed across the filling wall on the surface of the VCSEL for providing electrical communications.

2. The oxide-confined VCSEL of claim 1, wherein the filling material is a metal.

3. The oxide-confined VCSEL of claim 2, wherein the metal is selected from the group consisting of silver and aluminum.

4. The oxide-confined VCSEL of claim 1, wherein the filling material is conductive and an insulating layer is further inserted between the filling wall and the metal electrode to block electrical communications.

5. A method for manufacturing an oxide-confined VCSEL, which comprising the steps of:
providing a VCSEL, whose epitaxial structure contains a selective oxide current confinement region;
forming an etched groove on the surface of the VCSEL, deep enough to pass the selective oxide current confinement region;
oxidizing the exposed selective oxide current confinement region in the etched groove toward the center, so that an AlGaAs layer on the outer region of the selective oxide current confinement region is turned into an aluminum oxide dielectric layer, forming an oxide aperture with a low index of refraction;
filling a filling material in the etched groove to form a filling wall, planarizing the surface of the VCSEL; and
forming a metal electrode on the surface of the VCSEL across the filling wall for providing electrical communications.

6. The method of claim 5, wherein the filling material is a metal.

7. The method of claim 6, wherein the metal is selected from the group consisting of silver and aluminum.

8. The method of claim 5 further comprising the step of forming an insulating layer between the filling wall and the metal electrode to block electrical communications when the filling material is conductive.

9. The method of claim 5, wherein the step of oxidizing the exposed selective oxide current confinement region in the etched groove toward the center is achieved by supplying the etched groove with high-temperature water vapor.

10. The method of claim 5, wherein the step of forming an etched groove on the surface of the VCSEL is achieved using an anisotropic etching means.

11. The method of claim 5, wherein the step of filling a filling material in the etched groove to form a filling wall is achieved by combining the photolithography and evaporation methods.
